(19) United States
(12) Patent Application Publication
(10) Pub. No.: US 2024/0021754 A1
(43) Pub. Date: Jan. 18, 2024

(54) COMPOSITE SUBSTRATES, PHOTOELECTRIC DEVICES, AND MANUFACTURING METHODS THEREOF

(71) Applicant: ENKRIS SEMICONDUCTOR, INC., Suzhou, Jiangsu (CN)

(72) Inventors: Liyang Zhang, Suzhou, Jiangsu (CN); Kai Cheng, Suzhou, Jiangsu (CN)

(73) Assignee: ENKRIS SEMICONDUCTOR, INC., Suzhou, Jiangsu (CN)

(21) Appl. No.: 18/254,093

(22) PCT Filed: Nov. 25, 2020
(86) PCT No.: PCT/CN2020/131424

§ 371 Date: May 23, 2023

(51) Int. Cl. H01L 33/16; H01L 33/40; H01L 33/00

(52) U.S. Cl. CPC H01L 33/16; H01L 33/405; H01L 33/005

(57) ABSTRACT

A composite substrate, a photoelectric device and a preparation method therefor. The composite substrate comprises a base substrate and a nano-diamond structure located on the base substrate; the nano-diamond structure comprises a plurality of nano-diamond protrusions arranged at intervals, and a gap is provided between two adjacent nano-diamond protrusions. The photoelectric device comprises the composite substrate, and further comprises a first semiconductor layer, an active layer, and a second semiconductor layer stacked on the composite substrate; the first semiconductor layer comprises protruding portions and a flat portion sequentially stacked in the vertical direction, the protruding portions are in the gaps and correspond one-to-one to the gaps, and the flat portion is located on the protruding portions and the nano-diamond structure. The preparation method for the photoelectric device is used for manufacturing the photoelectric device.

### CROSS REFERENCE TO RELATED APPLICATIONS

This application is a US National Phase of a PCT Application No. PCT/CN2020/131424 filed on Nov. 25, 2020, the entire contents of which are incorporated herein by reference in their entireties.

### TECHNICAL FIELD

The present disclosure relates to the technical field of semiconductors, in particular to, composite substrates, photoelectric devices and manufacturing methods thereof.

### BACKGROUND

In recent years, LED (light-emitting diode) has gradually become one of the most valued light source technologies. On the one hand, LED has the characteristic of small size; On the other hand, LED has the characteristic of power saving by low current and low voltage driving; At the same time, LED further has many advantages such as solid structure, strong impact resistance and vibration resistance, and long service life. Especially in the ultraviolet region, AlGaN-based multi-quantum well ultraviolet LED (UV-LED) has shown significant advantages and become one of the hotspots in the development of ultraviolet photoelectric devices. AlGaN-based multi-quantum well UV-LED devices have broad application prospects. Ultraviolet light has great application value in fields such as screen printing, polymer solidification, environmental protection, air and water purification, medical treatment and biomedicine, white light lighting, military detection, and space security communication.

Due to the limited hole injection efficiency of the p-type Al GaN layer, it is difficult to form good ohmic contacts. Therefore, p-GaN layers are often used on a side of the p-type layer to make p-type ohmic contacts, to improve the hole injection efficiency of the p-type layer. However, due to the strong absorption and low reflectivity of ultraviolet light (200 nm-365 nm) of the p-GaN layer, the light radiating from the quantum well towards the p-type layer is absorbed by the p-GaN layer, which cannot be extracted, resulting in lower light extraction efficiency. The majority of the light that has not been extracted is absorbed and converted into heat, causing the temperature of the device to rise, seriously affecting the reliability of the device.

Therefore, how to avoid the serious absorption of short wavelength UV light by P-type layer and improve the light extraction efficiency is still a problem to be solved urgently.

### SUMMARY

The present disclosure provides a composite substrate, a photoelectric device, and a manufacturing method thereof.

According to a first aspect of the embodiments of the present disclosure, a composite substrate is provided. The composite substrate includes a base; and a nano-diamond structure on the base;

where the nano-diamond structure includes a plurality of nano-diamond protrusions spaced along a horizontal direction, and a gap is between two adjacent nano-diamond protrusions of the plurality of the nano-diamond protrusions.

In some embodiment, the plurality of the nano-diamond protrusions are nanoscale diamond crystalline grains, and particle sizes of the nanoscale diamond crystalline grains are less than or equal to 200 nm.

In some embodiment, a material of the nano-diamond structure includes boron-doped diamond material.

In some embodiment, a material of the nano-diamond structure includes a non-doped semiconductor material.

According to the second aspect of the embodiments of the present disclosure, a photoelectric device is provided. The photoelectric device includes:
the above composite substrate; and
a first semiconductor layer, an active layer and a second semiconductor layer that are stacked on the composite substrate, where a conductive type of the first semiconductor layer is opposite to a conductive type of the second semiconductor layer, and the conductive type of the first semiconductor layer is the same as a conductive type of the nano-diamond structure;
the first semiconductor layer includes convex parts and a flat part that are sequentially stacked along a vertical direction, the convex parts are in gaps, and the convex parts corresponds to the gaps respectively, the flat part is on the convex parts and the nano-diamond structure, and a side of the flat part far from the nano-diamond structure is a plane.

In some embodiment, materials of the first semiconductor layer and the second semiconductor layer are wide band gap semiconductor materials, and band gaps of the wide band gap semiconductor materials are greater than 2.0 eV.

In some embodiment, the photoelectric device further includes a first electrode and a second electrode,
where a groove is on the second semiconductor layer, which penetrates through the second semiconductor layer and the active layer, and at least a part of the first semiconductor layer is left below the groove,
the first electrode is on a bottom of the groove, and
the second electrode is on the second semiconductor layer.

In some embodiment, the photoelectric device further includes a first electrode and a second electrode, where the first electrode is beneath the composite substrate, and the second electrode is on the second semiconductor layer.

In some embodiment, the second electrode includes a reflector material.

According to the third aspect of the embodiments of the present disclosure, a manufacturing method of a photoelectric device is provided. The manufacturing method of a photoelectric device includes:
S1: forming a composite substrate, including: providing a base and forming a nano-diamond structure on the base, where the nano-diamond structure includes a plurality of nano-diamond protrusions spaced along a horizontal direction, and a gap is arranged between two adjacent nano-diamond protrusions of the plurality of the nano-diamond protrusions;
S2: forming a first semiconductor layer on the composite substrate, by epitaxially growing the first semiconductor layer using the nano-diamond protrusions as a mask, where the first semiconductor layer includes convex parts and a flat part that are sequentially stacked in a vertical direction, the convex parts are formed in gaps, the convex parts correspond to the gaps respectively, the flat part of the first semiconductor layer is formed on an upper surface of the nano-diamond structure and on the convex parts, a side of the flat part far from the nano-diamond structure is a plane, and a conductive type of the first semiconductor layer is the same as a conductive type of the nano-diamond structure; and
S3: sequentially forming an active layer and a second semiconductor layer on the first semiconductor layer, where a conductive type of the second semiconductor layer is opposite to the conductive type of the first semiconductor layer.

In some embodiment, the manufacturing method of a photoelectric device further includes:
S4: forming a groove on the second semiconductor layer by etching, where the groove penetrates through the second semiconductor layer and the active layer, and at least a part of the first semiconductor layer is left below the groove; and
S5: forming a first electrode on a bottom of the groove, and forming a second electrode on the second semiconductor layer.

In some embodiment, the manufacturing method of a photoelectric device further includes:
S4: thinning the composite substrate; and
S5: forming a first electrode beneath the composite substrate, and forming a second electrode on the second semiconductor layer.

### BRIEF DESCRIPTION OF THE DRAWINGS

FIG. 1 is a cross-sectional structure diagram of a composite substrate according to Embodiment 1 of the present disclosure.

FIG. 2 is a cross-sectional structure diagram of a photoelectric device according to Embodiment 1 of the present disclosure.

FIGS. 3(a) to 3(e) are process flow diagrams of a manufacturing method of the photoelectric device according to Embodiment 1 of the present disclosure.

FIG. 4 is a cross-sectional structure diagram of a photoelectronic device according to Embodiment 2 of the present disclosure.

FIGS. 5(a) to 5(b) are process flow diagrams of a manufacturing method of the photoelectric device according to Embodiment 2 of the present disclosure.

### DETAILED DESCRIPTION OF THE EMBODIMENTS

Exemplary embodiments will be described in detail herein, examples of which are illustrated in the accompanying drawings. Where the following description refers to the drawings, the same numerals in different drawings refer to the same or similar elements unless otherwise indicated. Embodiments described in the illustrative examples below are not intended to represent all embodiments consistent with the present disclosure. Rather, they are merely embodiments of devices and methods consistent with some aspects of the present disclosure as recited in the appended claims.

The present disclosure provides a composite substrate, a photoelectric device, and a manufacturing method thereof, which can effectively avoid absorbing UV light emitted by an active layer and achieve a beneficial effect of significantly improving the light extraction efficiency of UV-LED.

### Embodiment 1

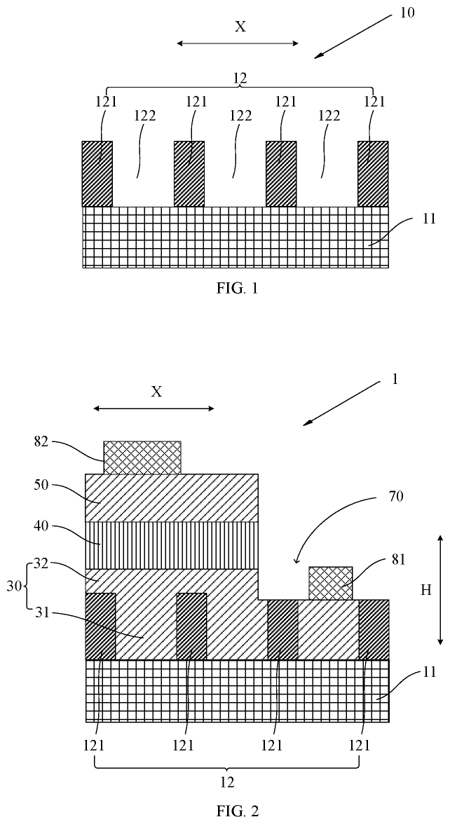

Based on FIG. 1, in this embodiment, a composite substrate 10 is provided. The composite substrate 10 includes a base 11 and a nano-diamond structure 12 on the base 11, where the nano-diamond structure 12 includes a plurality of nano-diamond protrusions 121 spaced along a horizontal direction X, and a gap 122 is between two adjacent nano-diamond protrusions 121.

A material of the nano-diamond structure 12 includes boron-doped diamond material, which is not limited. In other embodiments, the nano-diamond structure 12 can also include a non-doped semiconductor material.

The nano-diamond protrusion 121 is a nanoscale diamond crystalline grain, and the particle size of the nanoscale diamond crystalline grain is less than or equal to 200 nm.

In this embodiment, the nano-diamond structure 12 can be formed by a chemical vapor deposition (CVD) process. Through the CVD process, nanoscale diamond crystalline grains that are spaced can be directly formed.

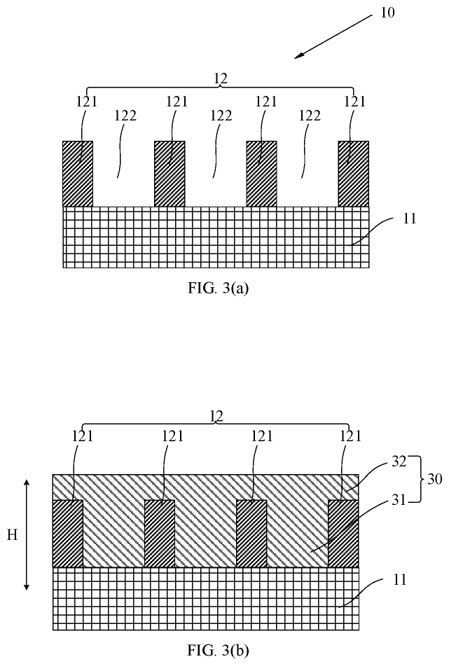

Based on FIG. 2, in this embodiment, a photoelectric device 1 is further provided. The photoelectric device 1 includes the above composite substrate 10, a first semiconductor layer 30, an active layer 40, and a second semiconductor layer 50 that are stacked on the composite substrate 10. A conductive type of the first semiconductor layer 30 is opposite to a conductive type of the second semiconductor layer 50, and the conductive type of the first semiconductor layer 30 is the same as a conductive type of the nano-diamond structure 12.

Specifically, the first semiconductor layer 30 includes a convex part 31 and a flat part 32 which are sequentially stacked along a vertical direction H, the convex part 31 is in the gap 122, and the convex parts 31 corresponds to the gaps 122 one by one, the flat part 32 is located on the convex parts 31 and the nano-diamond structure 12, and a side of the flat part 32 far from the nano-diamond structure 12 is a plane.

The materials of the first semiconductor layer 30 and the second semiconductor layer 50 are wide band gap semiconductor materials, and the band gaps of the wide band gap semiconductor materials are greater than 2.0 eV. Specifically, the wide band gap semiconductor materials are gallium nitride-based materials, boron nitride, indium tin oxide (ITO) or other materials, as long as they are combined with the nano-diamond structure 12.

The active layer 40 is a multi-quantum well structure.

In the embodiment, the photoelectric device 1 further includes a first electrode 81 and a second electrode 82.

The second semiconductor layer 50 is provided with a groove 70, which penetrates through the second semiconductor layer 50 and the active layer 40, and at least a part of the first semiconductor layer 30 is left below the groove 70. The first electrode 81 is located at the bottom of the groove 70 and is connected to the first semiconductor layer 30.

The second electrode 82 is provided on the second semiconductor layer 50 and is connected to the second semiconductor layer 50.

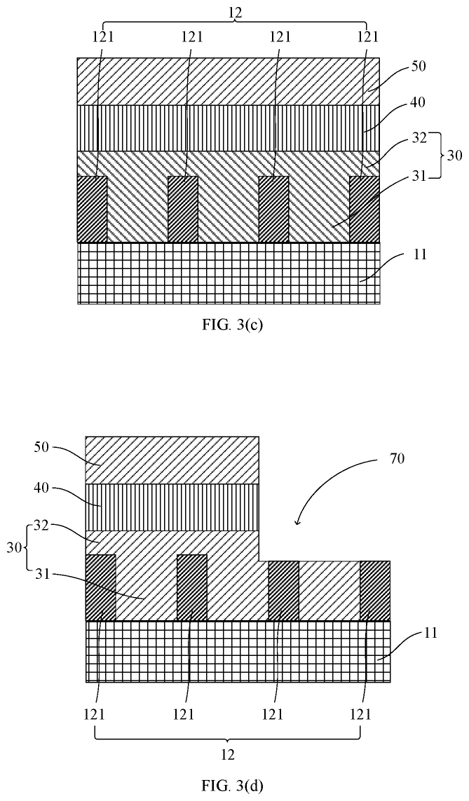

FIGS. 3(a) to 3(e) are process flow diagrams of a manufacturing method of the photoelectric device according to Embodiment 1 of the present disclosure. The manufacturing method is used for producing the above photoelectric device. The manufacturing method of the photoelectric device includes the following steps.

In step 100: forming a composite substrate, including: providing a base, and forming a nano-diamond structure on the base, where the nano-diamond structure includes a plurality of nano-diamond protrusions spaced along a horizontal direction, and a gap is arranged between two adjacent nano-diamond protrusions.

In step 200: forming a first semiconductor layer on the composite substrate, by epitaxially growing the first semiconductor layer using the nano-diamond protrusions as a mask, where the first semiconductor layer includes convex parts and a flat part that are sequentially stacked in the vertical direction, the convex parts are formed in the gap, the convex parts correspond to gaps one by one, the flat part of the first semiconductor layer is formed on an upper surface of the nano-diamond structure and on the convex parts, a side of the flat part far from the nano-diamond structure is a plane (flat surface), and the first semiconductor layer has the same conductive type as the nano-diamond structure.

In step 300: sequentially forming an active layer and a second semiconductor layer on the first semiconductor layer, where a conductive type of the second semiconductor layer is opposite to the conductive type of the first semiconductor layer.

In step 400: forming a groove on the second semiconductor layer by etching, where the groove penetrates through the second semiconductor layer and the active layer, and at least a part of the first semiconductor layer is left below the groove.

In step 500: forming a first electrode at a bottom of the groove, and forming a second electrode on the second semiconductor layer.

Specifically, as shown in FIG. 3(a), in step 100, forming a composite substrate 10 includes providing a base 11, and forming a nano-diamond structure 12 on the base 11 through a CVD process, where the nano-diamond structure 12 includes a plurality of nano-diamond protrusions 121 spaced along the horizontal direction X, and a gap 122 is provided between two adjacent nano-diamond protrusions 121.

In step 200, as shown in FIG. 3(b), a first semiconductor layer 30 is formed on the composite substrate 10, by epitaxially growing the first semiconductor layer 30 using the nano-diamond protrusions 121 as a mask, where the first semiconductor layer 30 includes convex parts 31 and a flat part 32 that are sequentially stacked in the vertical direction H, the convex part 31 is formed in the gap 122, the convex parts 31 correspond to the gaps 122 one by one, the flat part 32 of the first semiconductor layer 30 is formed on an upper surface of the nano-diamond structure 12 and on the convex parts 31, a side of the flat part 32 far from the nano-diamond structure 12 is a plane, and the first semiconductor layer 30 has the same conductive type as the nano-diamond structure 12.

In step 300, as shown in FIG. 3(c), an active layer 40 and a second semiconductor layer 50 are sequentially formed on the first semiconductor layer 30, where the conductive type of the second semiconductor layer 50 is opposite to the conductive type of the first semiconductor layer 30.

In step 400, as shown in FIG. 3(d), a groove 70 on the second semiconductor layer 50 is formed by etching the second semiconductor layer 50, where the groove 70 penetrates through the second semiconductor layer 50 and the active layer 40, and at least a part of the first semiconductor layer 30 is left below the groove 70.

In step 500, as shown in FIG. 3(e), a first electrode 81 is formed at the bottom of the groove 70, and a second electrode 82 is formed on the second semiconductor layer 50.

In this embodiment, by providing the composite substrate, the heat dissipation effect can be improved. Furthermore, in the composite substrate, the photoelectric device and the manufacturing method thereof provided by the embodiments, by providing a layer of nano-diamond structure on the base, and then forming the epitaxial structures of the photoelectric device on the nano-diamond structure, absorbing the UV light emitted by the active layer can be effectively avoided, thereby achieving the beneficial effect of greatly improving the light extraction efficiency of the UV-LED. This is because the nano-diamond structure has a weak absorption effect on the light of full wave band, which reduces the light absorption problem and can effectively improve the light output efficiency of LED, especially UV-LED. Besides, the band gap of diamond is large and has strong reflection effect on electrons, which can reduce electron leakage and improve brightness. Furthermore, the nano-diamond structure is easy to be doped, and the hole concentration is high, so it is easy to achieve ohmic contacts.

### Embodiment 2

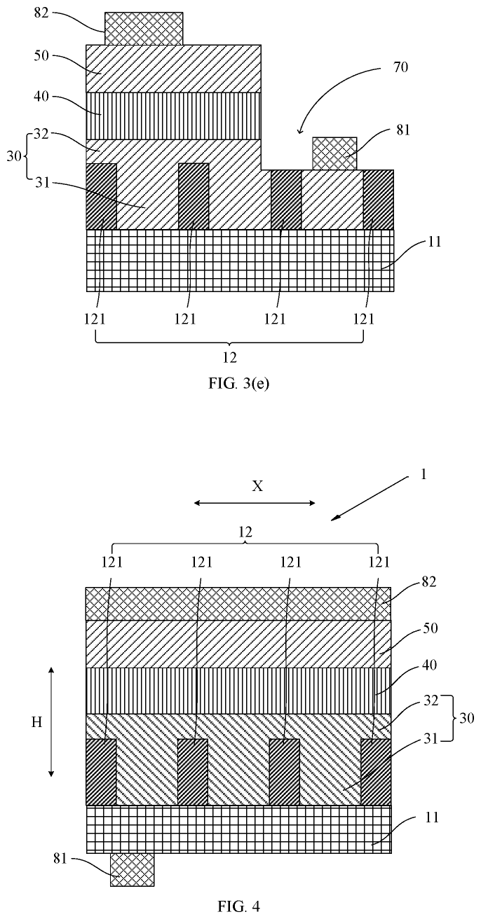

As shown in FIG. 4, in this embodiment, a photoelectric device 1 is provided. A structure of the photoelectric device 1 in Embodiment 2 is basically the same as the structure of the photoelectric device 1 in Embodiment 1, and the difference is that positions of the first electrode 81 and the second electrode 82 of the photoelectric device 1 in Embodiment 2 are different from the positions of the first electrode 81 and the second electrode 82 in Embodiment 1. Specifically, the first electrode 81 is provided beneath the composite substrate 10, and the second electrode 82 is provided on the second semiconductor layer 50.

Furthermore, the orthographic projection of the second electrode 82 on the second semiconductor layer 50 overlaps with the outer edge of the second semiconductor layer 50. The second electrode 82 contains a reflector material. Specifically, the reflector material includes a material such as aluminum, silver, titanium, or magnesium fluoride that has a reflective property.

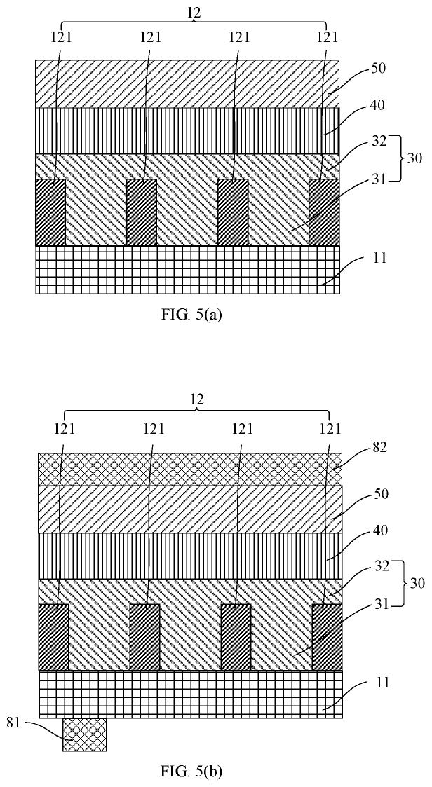

As shown in FIGS. 5(a) to 5(b), another aspect of this embodiment further provides a manufacturing method for the above photoelectric device. The manufacturing method of the photoelectric device is basically the same as the manufacturing method of the photoelectric device in Embodiment 1, and the difference is that after completing step S300, the manufacturing method of the photoelectric device further includes:

In step 400: as shown in FIG. 5(a), thinning the composite substrate 10; and

In step 500: as shown in FIG. 5(b), forming a first electrode 81 beneath the composite substrate 10, and forming a second electrode 82 on the second semiconductor layer 50.

In the composite substrate, the photoelectric device and the manufacturing method thereof according to the present disclosure, by providing a layer of nano-diamond structure on the base, and then forming all the epitaxial structures of the photoelectric device on the nano-diamond structure, it can effectively avoid absorbing the UV light emitted by the active layer, and achieve the beneficial effect of greatly improving the light extraction efficiency of the UV-LED. This is because the nano-diamond structure has a weak absorption effect on the light of full wave band, which reduces the light absorption problem and can effectively improve the light output efficiency of LED, especially UV-LED. Besides, the band gap of diamond is large and has strong reflection effect on electrons, which can reduce electron leakage and improve brightness. Furthermore, the nano-diamond structure is easy to be doped, and the hole concentration is high, so it is easy to achieve ohmic contacts. In addition, the present disclosure can improve the overall heat dissipation effect by providing the composite substrate.

The foregoing are only some preferred embodiments of the present disclosure and are not intended to limit the present disclosure, and any modifications, equivalent substitutions, improvements, etc., made within the spirit and principles of the present disclosure shall be included within the scope of protection of the present disclosure.

1. A composite substrate, comprising:
a base; and
a nano-diamond structure on the base, wherein the nano-diamond structure comprises a plurality of nano-diamond protrusions spaced along a horizontal direction, and a gap is between two adjacent nano-diamond protrusions of the plurality of the nano-diamond protrusions.

2. The composite substrate according to claim 1, wherein the plurality of the nano-diamond protrusions are nanoscale diamond crystalline grains, and particle sizes of the nanoscale diamond crystalline grains are less than or equal to 200 nm.

3. The composite substrate according to claim 1, wherein a material of the nano-diamond structure comprises boron-doped diamond material.

4. The composite substrate according to claim 1, wherein a material of the nano-diamond structure comprises a non-doped semiconductor material.

5. A photoelectric device, comprising:
the composite substrate according to claim 1; and
a first semiconductor layer, an active layer and a second semiconductor layer that are stacked on the composite substrate, wherein a conductive type of the first semiconductor layer is opposite to a conductive type of the second semiconductor layer, and the conductive type of the first semiconductor layer is the same as a conductive type of the nano-diamond structure, the first semiconductor layer comprises convex parts and a flat part that are sequentially stacked along a vertical direction, the convex parts are in gaps, and the convex parts corresponds to the gaps respectively, the flat part is on the convex parts and the nano-diamond structure, and a side of the flat part far from the nano-diamond structure is a plane.

6. The photoelectric device according to claim 5, wherein materials of the first semiconductor layer and the second semiconductor layer are wide band gap semiconductor materials, and band gaps of the wide band gap semiconductor materials are greater than 2.0 eV.

7. The photoelectric device according to claim 5, further comprising:
a first electrode and a second electrode, wherein a groove is on the second semiconductor layer, which penetrates through the second semiconductor layer and the active layer, and at least a part of the first semiconductor layer is left below the groove, the first electrode is on a bottom of the groove, and the second electrode is on the second semiconductor layer.

8. The photoelectric device according to claim 5, further comprising:
a first electrode and a second electrode, wherein the first electrode is beneath the composite substrate, and the second electrode is on the second semiconductor layer.

9. The photoelectric device according to claim 8, wherein the second electrode comprises a reflector material.

10. A manufacturing method of a photoelectric device, comprising:
S1: forming a composite substrate, comprising: providing a base and forming a nano-diamond structure on the base, wherein the nano-diamond structure comprises a plurality of nano-diamond protrusions spaced along a horizontal direction, and a gap is arranged between two adjacent nano-diamond protrusions of the plurality of the nano-diamond protrusions;
S2: forming a first semiconductor layer on the composite substrate, by epitaxially growing the first semiconductor layer using the nano-diamond protrusions as a mask, wherein the first semiconductor layer comprises convex parts and a flat part that are sequentially stacked in a vertical direction, the convex parts are formed in gaps, the convex parts correspond to the gaps respectively, the flat part of the first semiconductor layer is formed on an upper surface of the nano-diamond structure and on the convex parts, a side of the flat part far from the nano-diamond structure is a plane, and a conductive type of the first semiconductor layer is the same as a conductive type of the nano-diamond structure; and
S3: sequentially forming an active layer and a second semiconductor layer on the first semiconductor layer, wherein a conductive type of the second semiconductor layer is opposite to the conductive type of the first semiconductor layer.

11. The manufacturing method according to claim 10, further comprising:
S4: forming a groove on the second semiconductor layer by etching, wherein the groove penetrates through the second semiconductor layer and the active layer, and at least a part of the first semiconductor layer is left below the groove; and
S5: forming a first electrode on a bottom of the groove, and forming a second electrode on the second semiconductor layer.

12. The manufacturing method according to claim 10, further comprising:
S4: thinning the composite substrate; and
S5: forming a first electrode beneath the composite substrate, and forming a second electrode on the second semiconductor layer.
